(19) United States
(12) Patent Application Publication
(10) Pub. No.: US 2018/0208792 A1
(43) Pub. Date: Jul. 26, 2018

(54) FILM COATING AND FILM COATING COMPOSITIONS FOR SURFACE MODIFICATION AND METALLIZATION

(71) Applicant: Jun YANG, London (CA)

(72) Inventors: Jun YANG, London (CA); Mingjun HU, Ningbo City (CN); Tengyuan ZHANG, London (CN); Qiuquan GUO, London (CA)

(21) Appl. No.: 15/928,527

(22) Filed: Mar. 22, 2018

Related U.S. Application Data
(63) Continuation-in-part of application No. PCT/CN2016/099874, filed on Sep. 23, 2016.
(60) Provisional application No. 62/232,044, filed on Sep. 24, 2015.

(51) Int. Cl. C09D 139/08; B05D 3/06; B05D 3/02; C23C 18/42; C23C 18/16; C09D 7/20; C09D 7/63; C08J 7/04; H05K 3/12; H05K 3/18

(52) U.S. Cl. CPC C09D 139/08; H05K 2203/0783; B05D 3/0254; C23C 18/42; C23C 18/165; C09D 7/20; C09D 7/63; C08J 7/047; H05K 3/1208; H05K 3/182; C08J 2367/02; C08J 2439/08; H05K 2203/125; H05K 2203/072; B05D 3/067

(57) ABSTRACT

The present disclosure provides a coating composition for use in coating polyester film, polyimide film, polyvinyl chloride film, semi-embossed film, polyvinyl chloride film and like, comprises poly(4-vinyl pyridine), SU-8, a solution such as isopropyl alcohol, 1,4-dioxane. A simple universal solution-based coating method for fast surface modification of various substances by applying an effective amount of pyridine ligands to immobilize transitional metal ions that can behave as the catalyst of electroless copper plating for surface metallization while functioning as the adhesion-promoting layer between the substrate and deposited metal.

### FIELD

The present disclosure relates to the field of solution-based film coating of substrates like polyester film, polyimide film, polyvinyl chloride film, semi-embossed film, polyvinyl chloride film and like, and is specifically concerned with coating substrates with a coating based on SU-8 and poly(4-vinyl pyridine) (P4VP).

### BACKGROUND

Recently, flexible electronics have been gaining increasing research interest due to their promising applications in many practical fields, such as wearable electronics, portable devices, medical implants, etc. (see for example S. R. Forrest, Nature 2004, 428, 911-918; D. H. Kim, N. S. Lu, R. Ma, Y. S. Kim, R. H. Kim, S. D. Wang, J. Wu, S. M. Won, H. Tao, A. Islam, K. J. Yu, T. I. Kim, R. Chowdhury, M. Ying, L. Z. Xu, M. Li, H. J. Chung, H. Keum, M. McCormick, P. Liu, Y. W. Zhang, F. G. Omenetto, Y. G. Huang, T. Coleman, J. A. Rogers, Science 2011, 333, 838; Y. G. Sun, J. A. Rogers, Adv. Mater. 2007, 19, 1897-1916). Flexible circuit, as “blood circulation system” of flexible electronic products, plays an especially important role. Attributed to flexible digital processing mode and a rapid scalable manner, nowadays printing techniques are providing a powerful tool for the fast design and fabrication of different patterns. The application of printing technique in fabricating flexible electronics will undoubtedly open a new door for the production of flexible circuits. Since the printer can make patterns in a high-efficiency mode, the conversion of printed patterns into conductive circuits naturally becomes the crux of the question. Electroless metal deposition (ELD), relying on an autocatalytic redox reaction to deposit a thin-layer of metal on a catalyst-preloaded substrate, provides a good solution to this question (see for example R. S. Guo, Y. Yu, Z. Xie, X. Liu, X. Zhou, Yufan Gao, Z. Liu, F. Zhou, Y. Yang, Z. Zheng, Adv.; M. S. Miller, H. L. Filiatrault, G. J. E. Davidson, M. Luo, T. B. Carmichael, J. Am. Chem. Soc. 2010, 132, 765-772; T. Zhang, X. Wang, T. Li, Q. Guo and J. Yang, J. Mater. Chem. C, 2014, 2, 286-294.) With the assistance of printing techniques, active catalysts can be deployed on the specified area of a flexible substrate, and thus induce the formation of the as-required metal pattern.

However, as an open problem, it is known that untreated flexible plastics cannot well grasp catalyst moieties due to lacking binding sites, and simple physical absorption usually results in the diffusion of catalyst into ELD solution and poor adhesion of as-deposited metal to the substrate, and further leads to bad coating quality especially when metal layer become thick, such as delamination and metal bump, and thus it is necessary to modify the surface of flexible substrate for effective uptake of catalyst moieties and improved adhesion of as-deposited metal to the substrate.

Currently, there are mainly two general approaches for surface modification of plastics, which can be classified into surface reforming and surface addition. Surface reforming refers to changing surface roughness or making active functional groups on the original surface via an in-situ oxidizing reaction, such as chemical etching, oxygen plasma. (A. Garcia, T. Berthelot, P. Viel, A. Mesnage, P. Jégou, F. Nekelson, Sébastien Roussel, S. Palacin, ACS Appl. Mater. Interfaces 2010, 2, 1177-1183; J. B. Park, J. S. Oh, E. L. Gil, S. J. Kyoung, J. T. Lim, G. Y. Yeom, J. Electrochem. Soc., 2010, 157, D614-D619).

Surface addition refers to adding an extra active layer onto existing plastic surfaces, typically including polymer grafting, (see for example A. Garcia, J. Polesel-Maris, P. Viel, S. Palacin, T. Berthelot, Adv. Funct. Mater. 2011, 21, 2096-2102; A. Garcia, T. Berthelot, P. Viel, P. Jégou, S. Palacin, ChemPhysChem 2011, 12, 2973-2978) surface silanization (see for example S. Sawada, Y. Masuda, P. Zhu, K. Koumoto, Langmuir 2006, 22, 332-337; Y. Chang, C. Yang, X.-Y. Zheng, D.-Y. Wang, Z.-G. Yang, ACS Appl. Mater. Interfaces 2014, 6, 768-772) and layer-by-layer deposition of polyelectrolytes, (see for example K. Cheng, M.-H. Yang, W. W. W. Chiu, C.-Y. Huang, J. Chang, T.-F. Ying, Y. Yang, Macromol. Rapid Commun. 2005, 26, 247-264; T. C. Wang, B. Chen, M. F. Rubner, R. E. Cohen Langmuir 2001, 17, 6610-6615) etc.

As is described, herein there are mainly two purposes for surface modification of flexible substrates, namely realizing selective and efficient uptake of catalyst moieties, and improving the adhesion between the substrate and metal. Consequently, surface modification of plastic substrates should at least address these two aspects. On the one hand, modified surfaces must contain the functional groups that can effectively grasp and hold catalyst moieties; on the other hand, the modified surfaces should be chemically resistant to electroless plating bath and further play or act as a buffer layer between original substrate and metal for better adhesion.

A lot of reports have indicated that modified surface by different methods can enhance the compatibility of metal and organic plastics, but most of them are still far away from being exploited in scalable low-cost applications, either due to complex or environment-unfriendly technological processes, or because of the difficulty in scaling up. For instance, typical chromium-containing etching agent for surface modification of printed circuit boards have been prohibited in many countries due to its harm to the environment; ligand-containing silane modified film is not acid or alkali resistant, and thus cannot withstand long-time electroless metal deposition because most of metal plating bath is relatively alkali; the grafting of polymer brush usually involves complex steps and harsh requirements for experimental conditions; layer-by-layer polyelectrolyte deposition is extremely slow and low-efficiency and will cost too much time due to tens of repeated coating operation. Therefore, these methods are not suitable for surface modification of large-area flexible plastics on a large scale.

P4VP molecules can be directly coated on the surface of plastic substrates, but simple physical absorption usually results in poor adhesion of the resulting modified layer. Thus there is a need to develop a more cost effective method for enhanced adhesion of P4VP molecules on the substrates. As early as the 1980s, it had been found that pyridine molecules can help to cure epoxy, (Xue, G.; Ishida, H.; Konig, J. L. Makromol. Chem., Rapid Commun. 7 (1986) 37; Idem., Angew. Makromol. Chem. 142 (1986) 17) and subsequently P4VP also shows the ability to cross link epoxy. (Meng, F.; Zhang, W.; Zheng, S. J. Mater. Sci. 40 (2005) 6367-6373).

### SUMMARY

The present disclosure provides a coating composition, comprising:

a mixture of two pre-prepared solutions, the first solution comprising poly (4-vinyl pyridine) dissolved in a first solvent which is any one of 2-propanol, methanol, ethanol, and acetone, the second solution comprising SU-8 dissolved in a second solvent which is any one of 1,4-dioxane, gamma-butyrolactone (GBL) and cyclopentanone, the poly (4-vinyl pyridine) being present in the mixture in a range from about 0.5% to about 4% by weight/volume of the composition, the SU-8 being present in the mixture in a range from about 0.05% to about 1% by weight/volume of the composition, the remainder of the composition up to 100% being the first and second organic solvents, the coating composition being used for use in coating a substrate.

The first organic solvent may be 2-propanol, and the second solvent may be 1,4-dioxane.

In the present method disclosed herein, based on the crosslinking reaction between the epoxy resin thermal initiators pyridine ring, inventors use the SU-8 molecule and poly (4-vinylpyridine) (the P4VP) film-forming solution as a main component, wherein SU-8 as a curing agent and a binder, the P4VP as the metal-ligand, followed by dipping in the surface of the plastic substrate was then cured.

In the present invention, film coating composition preferably comprises one or more ingredients: Poly (4-vinylpyridine), SU-8,1,4-dioxane, 2-propanol and ethanol.

The process disclosed herein employs epoxy to cross link P4VP molecules. On the one hand, epoxy has strong reactivity and can form good chemical and mechanical adhesion with polymer substrates; and on the other hand, epoxy molecules can also react with each other and P4VP molecules to build up a cross-linked polymer network on the substrate.

According to the present process, a pair of film substrate, such as polyester film, polyimide film, polyvinyl chloride film, polyvinyl chloride film and the semi-like embossed film, coating method comprising the steps of: 1) poly (4-vinylpyridine), 2) SU-8 was dissolved in a mixture of 1,4-dioxane and 2-propanol to form a uniform coating solution; a sufficient amount of the coating solution by dipping coating, spin coating, knife coating, inkjet printing, screen printing and the like is applied to the surface of a substrate to form a uniform thin film coating on the substrate; a thin film coating on the substrate placed in an oven baking. For different coating techniques described above, in order to make containing poly (4-vinylpyridine), the coating solution SU-8,1,4-dioxane and 2-propanol to achieve the desired properties, such as surface Zhang Li and viscosity, but a more desirable alternative solution is the incorporation of one or more of the following ingredients in the coating solution: glycerol, ethanol, polyvinylpyrrolidone, polyethylene glycol, a surfactant.

Poly (4-vinylpyridine) (P4VP) is an excellent surface for capturing a transition metal ion of the modifier, because of its good alcohol solubility, chelating power load capability and coordinating metal. 4-vinyl pyridine, as a reactive monomer having, in situ polymerization may be initiated by ultraviolet light or plasma, and therefore can be used for modification of the substrate surface.

SU-8 as a bridge agent P4VP molecules may be anchored to the substrate surface. Due to the strong covalent bonding, coating so formed may good adhesion to the substrate. Further, as a result of ring-opening reaction of epoxy groups, the carbon-oxygen bond to be the main type of bond. Compared to other silicone polymer grafted group and an ester bond, an ether bond and oxygen more alkali resistance. This plating solution, electroless copper plating deposition is very beneficial for the subsequent alkaline.

A further understanding of the functional and advantageous aspects of the present disclosure can be realized by reference to the following detailed description and drawings.

### BRIEF DESCRIPTION OF THE DRAWINGS

Embodiments disclosed herein will be more fully understood from the following detailed description thereof taken in connection with the accompanying drawings, which form a part of this application, and in which:

FIG. 1a P4VP using SU-8 and PET film coated with a mixture of a schematic flow diagram;

FIG. 1b is a photograph of a pure transparent PET film is thin;

FIG. 1c is a PET film using SU-8 and the P4VP modified;

FIG. 1d 1 h is covered by a PET film with a copper plating copper layer.

FIG. 2a P4VP respectively, and SU-8 P4VP composite coating, and SU-8 P4VP composite coating without NaOH treatment, after treatment P4VP 1M NaOH 1 hour after curing SU-8 and the composite coating FT-IR Spectrum;

FIG. 2b is a diagram of the contact angle of pure water and the PET film;

FIG. 2c is a schematic view of a contact angle of water with the modified PET film;

FIG. 2d is a schematic view of water treatment and post-curing modified PET film contact angle of sodium hydroxide;

FIG. 3a is a laser printer to produce a flexible circuit schematic printed on the surface modification of toner base reticle;

FIGS. 3b and 3c are two circuit patterns on the two different sides of the same piece of PET film;

FIGS. 4a and 4b are SEM images of the surface of a copper layer of copper over 10 min;

FIGS. 4c and 4d are 30 min, and 1 h after the copper plating layer on the surface SEM image;

FIGS. 4e and 4f respectively through 1 h, 12 h copper deposition layer of copper cross-sectional SEM image.

FIG. 5 shows the surface resistivity of the copper layer versus plating time and a copper plating layer thickness increases with plating time.

FIGS. 6a to 6f show cross-sectional SEM images of layers with different thickness of the copper plating of time of 20 min, 30 min, 40 min, 50 min, 60 min, and 120 min respectively for FIGS. 6a-f.

The following examples illustrate the present invention and its use in the manufacture of printed electronics.

### DETAILED DESCRIPTION

Various embodiments and aspects of the disclosure will be described with reference to details discussed below. The following description and drawings are illustrative of the disclosure and are not to be construed as limiting the disclosure. The drawings are not to scale. Numerous specific details are described to provide a thorough understanding of various embodiments of the present disclosure. However, in certain instances, well-known or conventional details are not described in order to provide a concise discussion of embodiments of the present disclosure.

As used herein, the terms “comprises” and “comprising” are to be construed as being inclusive and open ended, and not exclusive. Specifically, when used in the specification and claims, the terms “comprises” and “comprising” and variations thereof mean the specified features, steps or components are included. These terms are not to be interpreted to exclude the presence of other features, steps or components.

As used herein, the term “exemplary” means “serving as an example, instance, or illustration,” and should not be construed as preferred or advantageous over other configurations disclosed herein.

As used herein, the terms “about” and “approximately” are meant to cover variations that may exist in the upper and lower limits of the ranges of values, such as variations in properties, parameters, and dimensions.

### Preparation of Coating Compositions

The present disclosure provides coatings for coating various substrate materials which may be planar or have 3D shapes. The substrate materials may include, but are not limited to, plastics, paper products (cellulose based products for example) including regular paper, cotton based products, synthetic paper, textiles, and wood based products. Non-limiting exemplary plastics that may be used include, but are not limited to, polyesters, polyimides, polyvinyl chlorides, semi-embossed films, polypropylenes, acrylics, acrylonitrile butadiene styrene (ABS) materials, polycarbonate materials, polyethylene terephthalate (PET) materials,

In the compositions and process for making coatings using these compositions, based on the thermally initiated cross-linked reaction between epoxy and pyridine rings, SU-8 molecules and poly (4-vinyl pyridine) (P4VP) are used as the main components of a film-making solution, in which SU-8 behaves as curing agent and adhesive, and P4VP acts as metal ligand, and then dip coat on the surface of plastic substrate followed by low-temperature curing.

The film coating composition includes poly (4-vinyl pyridine) and SU-8 dissolved in organic liquids.

In accordance with the present disclosure, a method of coating plastic substrates, such as, but not limited to, polyesters, polyimides, polyvinyl chlorides, semi-embossed films, polypropylenes, acrylics, acrylonitrile butadiene styrene (ABS) materials, polycarbonate materials, polyethylene terephthalate (PET) materials, and like with a film coating, comprises the steps of dissolving 1) poly(4-vinyl pyridine), 2) SU-8 into one or more organic solvents forming a mixture to form an uniform coating solution, applying an effective amount of the coating solution onto the substrates using dip-coating, spin-coating, blade coating, inkjet printing, screen printing and like to form an uniform film coating on the substrates, and baking the film coating on the substrates in an oven, optionally, but preferably, one or more of the following components is/are mixed into the coating solution with the poly(4-vinyl pyridine), SU-8, 1,4-dioxane and 2-propanol to achieve the desired properties such as surface tension, viscosity etc. for different coating techniques mentioned above: glycerol, ethanol, polyvinyl pyrrolidone, polyethylene glycol, surfactant and like.

1,4-dioxane and 2-propanol are preferred organic solvents.

Poly (4-vinyl pyridine) (P4VP) has been a good candidate of surface modifiers used for uptake of transitional metal ions attributed to its good alcohol solubility, chelating ability, and pyridine ligands-bearing. 4-vinyl pyridine, as a kind of reactive monomer, can be used to modify substrate surfaces by in-situ polymerization under UV or plasma.

SU-8 plays a bridging agent to anchor P4VP molecules on the substrate surface. Attributed to strong covalent bonding, as-formed coating layer will have a good adhesion to the substrate. Furthermore, as a result of ring opening reaction of epoxide groups, carbon-oxygen bonds will be the dominant bonding type. In contrast to silicon-oxygen bond and ester groups in other polymer grafting, carbon-oxygen ether bonds are more alkali resistant. It is absolutely beneficial for subsequent electroless copper deposition in basic bath.

Preferably, the poly (4-vinyl pyridine) (P4VP) is dissolved in 2-propanol to form a uniform solution, the preferred concentration is 1 w/v %˜8 w/v %, more preferred 3 w/v %˜6 w/v %. Preferably, the SU-8 is dissolved in 1, 4-dioxane to obtain a uniform solution as well, the preferred concentration is 0.1 w/v %˜2 w/v %, more preferred 0.3 w/v %˜1 w/v %. Preferably the two solutions are mixed to get a transparent coating solution. The preferred solution contains 0.5 w/v %˜4 w/v % P4VP and 0.05 w/v %˜1 w/v % SU-8, more preferred 1.5 w/v %˜3 w/v/o P4VP and 0.15 w/v %˜0.5 w/v % SU-8.

The coating composition of the present invention in a concentration range of each component is as follows, in mass/volume:

The ranges of each components of the coating composition of the invention are as follows, by weight/volume:

| | ACCEPATABLE | PREFERRED |
|---|---|---|
| COMPONENT | RANGES (w/v %) | RANGES (w/v %) |
| poly (4-vinyl pyridine) | 0.5 to 4 | 1.5 to 3 |
| (P4VP) | | |
| SU-8 | 0.05 to 1 | 0.15 to 0.5 |
| 1,4-dioxane | 47 to 50 (v/v %) | 48.25 to 49.75 (v/v %) |
| 2-propanol | 47 to 50 (v/v %) | 48.25 to 49.75 (v/v %) |

### Fabrication of Printed Circuits

Once the selected composition is applied to the surface of an object, whether it be rigid or flexible, and been cured, the coated object is ready to have circuits produced in the coating through pattern the catalyst on the substrate. The catalyst can also be prepared in a liquid form suitable for application to a substrate by a chosen printing technique. The catalysts may be silver ions, and the noble metal salts of various noble metals such as, but not limited to, palladium (Pd), platinum (Pt) and gold (Au). The patterning of catalyst can be performed by any known printing technique. The catalyst ions bind with the pyridine ligands in the P4VP. Once the substrate is dried, a pattern of the ultimate circuit is formed with catalyst for the following electroless deposition process.

After this, the catalyst impregnated coating is placed into an electroless plating bath containing a metal ion for 1-120 min and of the metal to be deposited, wherein the plating bath can be Cu plating, Ni plating, gold plating and Ag plating. The electroless deposition is conducted by immersing into a plating bath for 1-120 min, wherein the plating bath can be Cu plating, Ni plating and Silver plating. The deposition process involves several simultaneous reactions in an aqueous solution, which occur without the use of external electrical power. The reaction is accomplished when hydrogen is released by a reducing agent, and the metal salt is reduced into metal on the substrate.

Various metals may be used to form the circuit patterns, including but not limited to copper (Cu), nickel (Ni), gold (Au), and silver (Ag).

The following examples illustrate the invention and its use in the fabrication of printed electronics.

### Example 1

The poly (4-vinyl pyridine) is dissolved in 2-propanol to form 4 w/v % solution, and SU-8 is dissolved in 1,4-dioxane to obtain 0.4 w/v % solution. Then the two solutions were mixed at 1:1 ratio to get a transparent solution. The final solution contains 2 w/v % P4VP and 0.2 w/v % SU-8.

Transparent PET film is cleaned by the mixed solution of 1:1 ethanol and acetone, and then is treated with oxygen plasma followed by dip coating or directly immersed into the film-making solution for dip-coating without oxygen plasma introduced. After 30 seconds, the film is drawn out of the solution slowly and dried in air. In the next, the coated film is put into oven of 120° C. for 20 mins for in-situ cross-linking reaction of P4VP and SU-8. The thickness of coated layer can be controlled by adjusting the concentration of P4VP and SU-8 in mixed solvent of 2-propanol and 1, 4-dioxane.

Upon completion of the coating process, the PET film shows a smooth surface with excellent surface uniformity. The film coating on the PET substrate possesses an excellent long-lasting uniformity, minimal tackiness, good film adhesion.

| COMPONENT | PERCENTAGE | | AMOUNT | |
|---|---|---|---|---|
| poly (4-vinyl pyridine) | 2 | w/v % | 2 | grams |
| (P4VP) | | | | |
| SU-8 | 0.2 | w/v % | 0.2 | grams |
| 1,4-dioxane | 50 | v/v % | 50 | mL |
| 2-propanol | 50 | v/v % | 50 | mL |

To demonstrate the functionality of the coating process disclosed herein, AgNO₃ was dissolved into deionized water to get 1 w/v % AgNO3 solution, and the coated PET film is soaked into the AgNO₃ solution for 10 seconds for the uptake of silver ions. Then the film is washed several times by water to remove free silver ions that did not bond with pyridine ligands. The film is dried and put into electroless copper plating bath for different time. Electroless copper plating bath consists of CuSO4.5H₂O (14 g/L), NaOH (12 g/L), potassium sodium tartrate (16 g/L), EDTA.2Na (20 g/L), HCHO (16.5 mL/L), 2, 2′-dipyridyl (20 mg/L), and potassium ferrocyanide (10 mg/L).

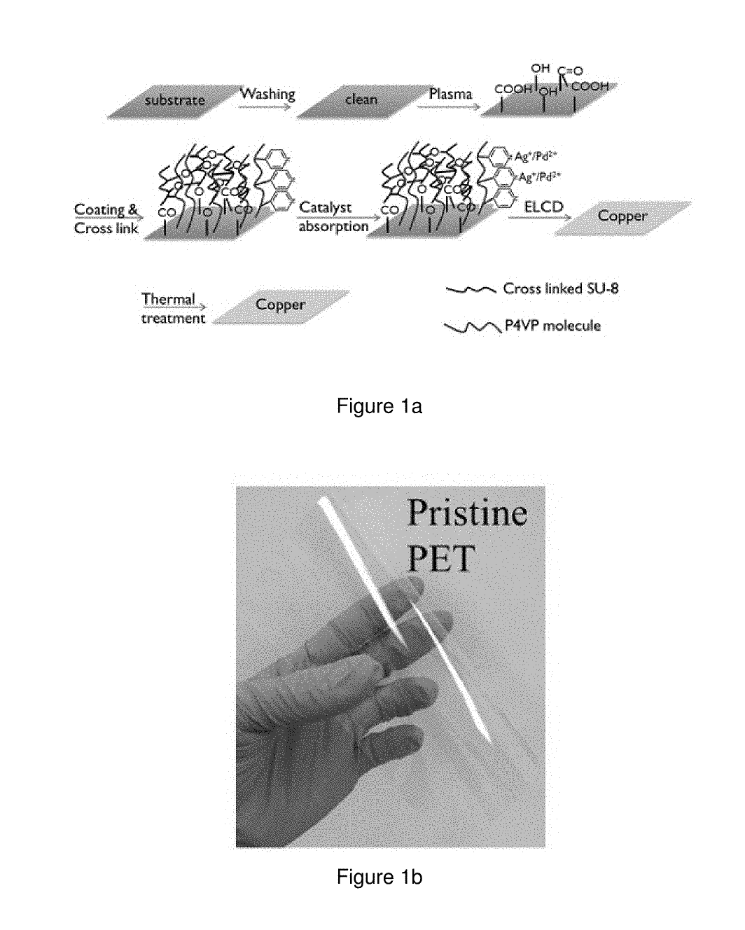

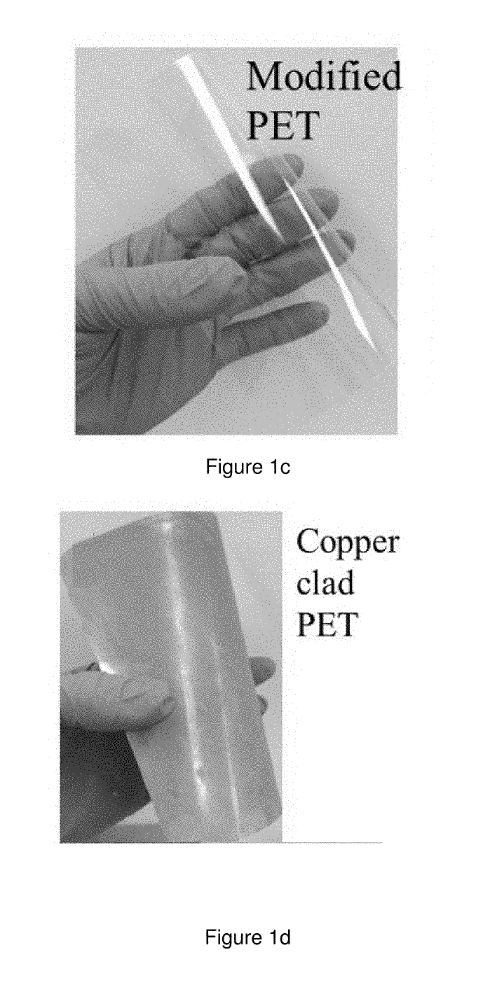

FIG. 1a shows the schematic flow of coating PET film by P4VP and SU-8 composites. Oxygen plasma was employed for surface activation to introduce oxygen-containing groups and free radicals on the surface. In principle, these active groups excited by plasma can react with the epoxide groups of SU-8 to form covalent bonding. FIGS. 1b and 1c present the digital photos of pristine transparent PET film and P4VP and SU-8 modified PET film respectively. It can be seen that, although coated by a layer of P4VP and SU-8 composites, the film is still flexible and highly transparent. The introduction of a thin-layer of P4VP and SU-8 composites did not affect the appearance and mechanical properties of PET film in any significant way.

To further demonstrate the inner principle of the invented coating composition, FT-IR analysis is performed using FT-IR NICOLET 6700 (Thermo Scientific Co.). The contact angle of water with different substrates was measured by Ramé-Hart Contact Angle Goniometer.

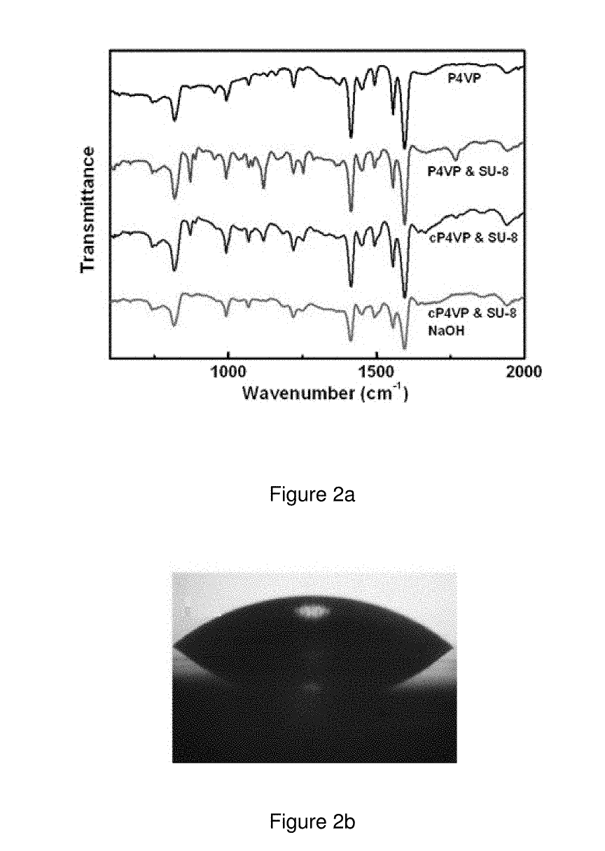

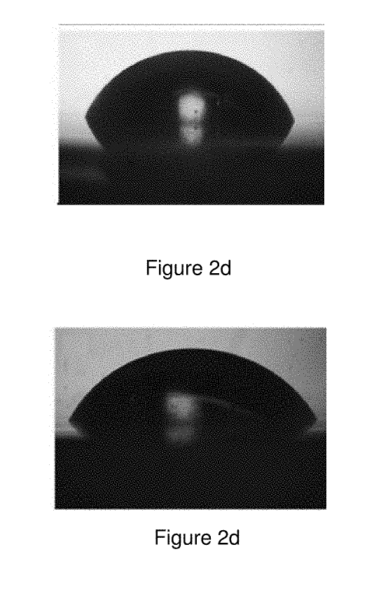

FIG. 2a shows FT-IR spectrum of P4VP (first spectrum at the top) and its composites (P4VP & SU-8, second spectrum down from the top) coated on the substrates. Different spectra present some discrepancies in peak position and intensity. In reference of standard infrared absorption of different functional groups, we can get much information from the spectra. The peaks located in 871 cm⁻¹ match well with the absorption of the benzene ring, which indicates the presence of SU-8 in the composite coating layer. It can also be seen that, after curing, the epoxide groups at 915 cm⁻¹ almost completely disappear, which demonstrates that strong reactive epoxide groups were nearly all consumed at the relatively high curing temperature. In addition, the vibrational absorption at 1664 cm⁻¹ that belongs to amide groups was enhanced, which further indicates that a cross-linking reaction occurred between pyridine groups and epoxide groups, and new amide groups-bearing products were formed, which is consistent with other research reports. In addition, there are two strong absorption peaks between 1500 cm⁻¹ and 1600 cm⁻¹ for all the coating layers, which belong to pyridine rings of P4VP molecules. Before and after curing, the strength and position of the two peaks did not almost change a lot. It indicates that, during curing process, only a small amount of pyridine ligands are consumed by epoxide groups due to much higher content of P4VP in the composites, and a lot of residual pyridine ligands will be available for the uptake of catalyst moieties in the following steps.

FIG. 2a also presents an FT-IR spectrum of a cured P4VP and SU-8 composite layer (designated cP4VP and SU-8 NaOH, fourth spectrum down from the top) treated by 1 M NaOH for 1 h. The spectrum is nearly the same with the sample untreated by NaOH (designated cP4VP and SU-8, third spectrum down from the top), which means that the initial coating layer was still well maintained on the surface of the substrate, and can withstand the erosion of basic solution to some extent.

FIG. 2b show the contact angle of water with pristine PET film, and it is about 46 degrees. After surface modification, the contact angle increase to about 77 degree (FIG. 2c) maybe due to the introduction of hydrophobic SU-8. After being treated by NaOH, the contact angle decreases slightly (FIG. 2d) but is still much larger than that on pristine PET.

It is evident that the coating process disclosed herein changes the surface energy of PET, and makes PET more hydrophobic. While enhanced hydrophobicity may not favorable for the wettability of the PET film, it can prevent excessive spreading of aqueous ink, and will be helpful for improving the resolution of printed ink on the PET substrate once the modified film was used as the substrate of inkjet printing.

In the following Example 2, functional circuits are fabricated using the coating composition disclosed herein. Scanning electron microscopy (SEM) studies were conducted to further demonstrate the functionality of this the present process.

### Example 2

The coating composition and coating methods are exactly the same as that in Example 1. The coated PET film is activated by 1 w/v % AgNO₃ solution by soaking the film into the solution for 10 seconds, and then dried for printing. Commercial HP laser printer 6700 is used for the printing of toner mask. After printing, the film is put into the oven of 90° C. for 1 min for the stabilization of toner mask, and then soaked into electroless copper plating bath for different time. The exposed area will be coated by copper, and copper cannot be formed in the place covered by mask due to the deactivation of the catalyst. After obtaining certain thickness of copper pattern, the mask layer can be washed in acetone by sonication or washed directly by dichloromethane or tetrahydrofuran.

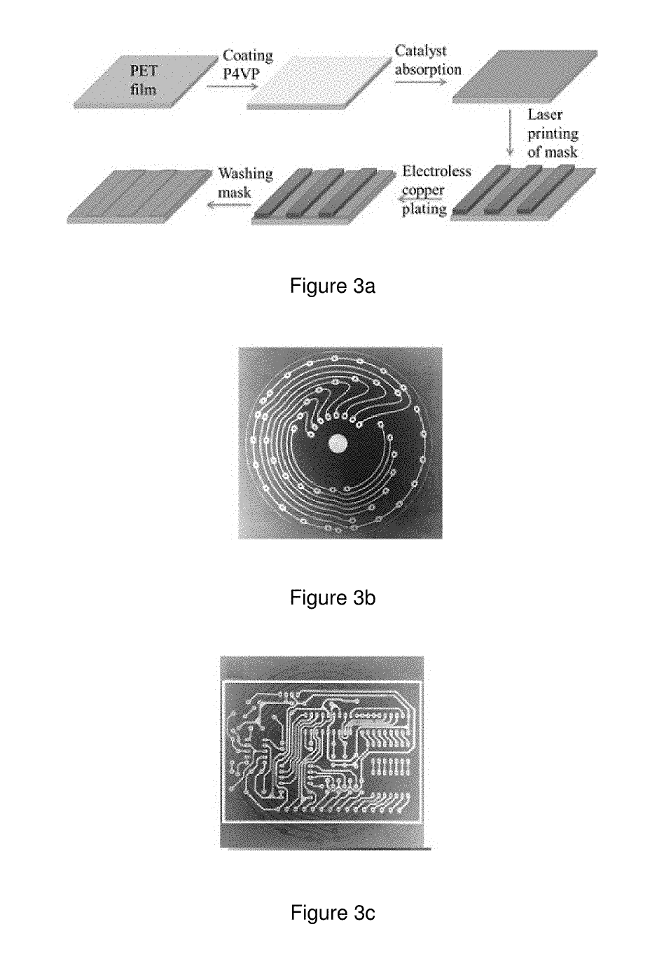

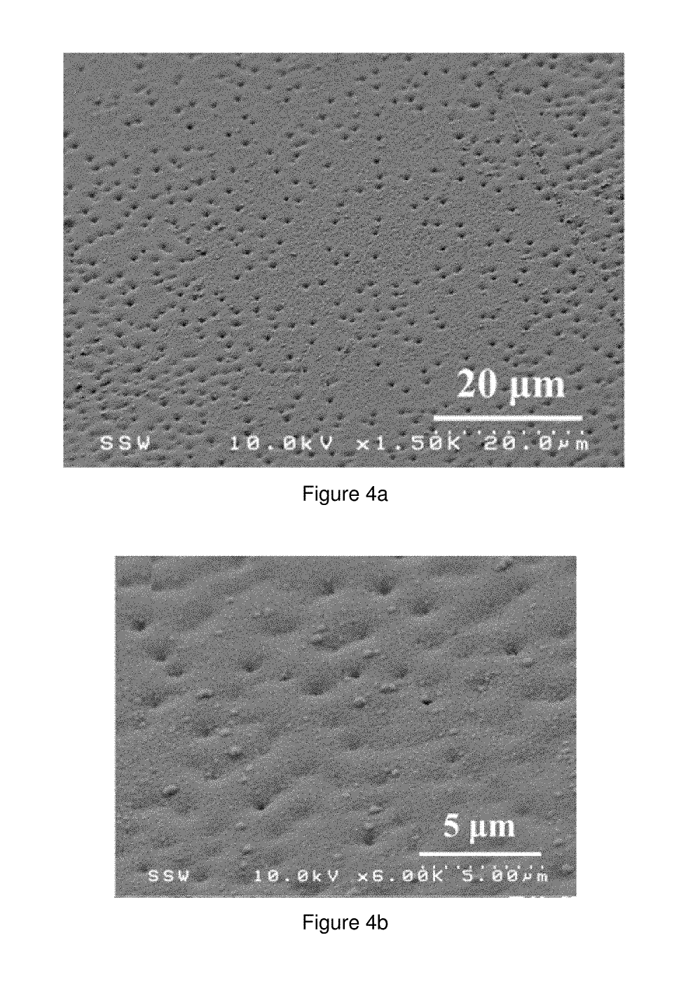

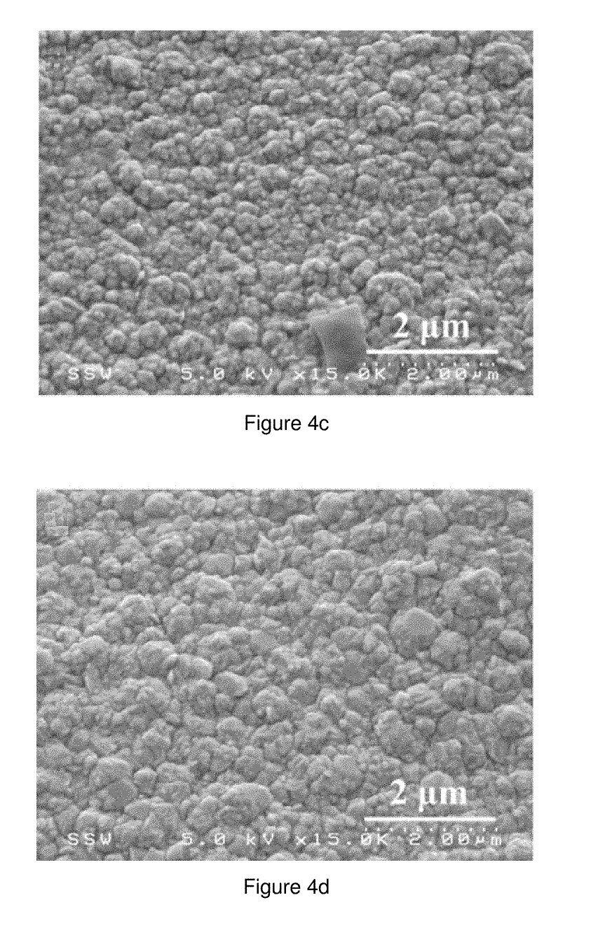

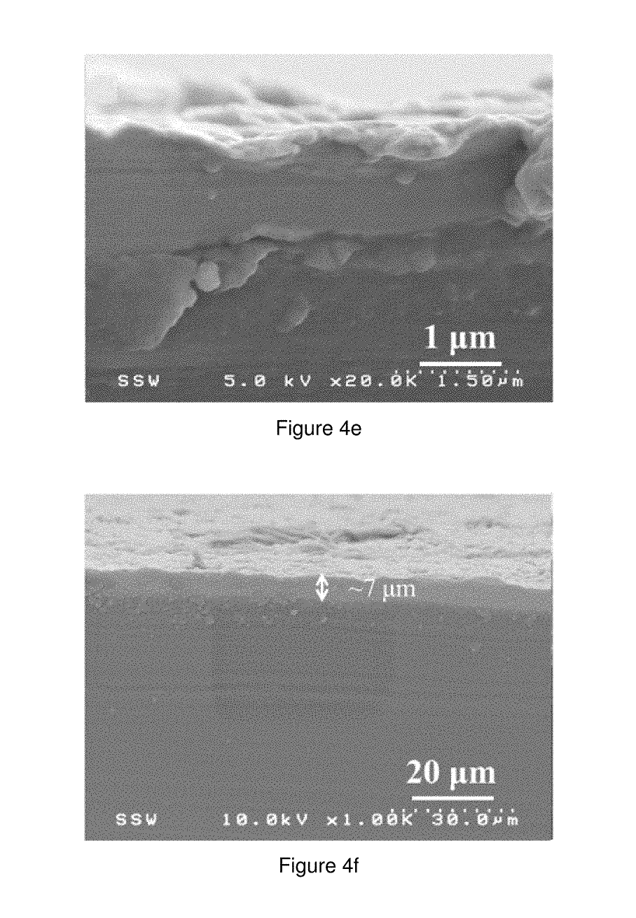

FIG. 3a shows the detailed schematic diagram for the production of flexible circuits by employing laser printer to print toner mask on the modified substrates. FIGS. 3b and 3c show two circuit patterns presented on two different sides of one piece of PET film. The green area is the printed toner. The SEM images and energy-dispersive X-ray (EDX) spectrum are taken by a Hitachi S-4500 field-emission scanning electron microscope (FE-SEM) at a 5 kV accelerating voltage. FIGS. 4a to 4f show SEM images of as-deposited copper layers. The surface morphology of copper layer with 10 mins of copper plating was displayed in FIGS. 4a and 4b. A lot of small pits on the surface of copper layers can be observed that may be attributed to soft template effects of hydrogen bubbles generated during electroless copper plating.

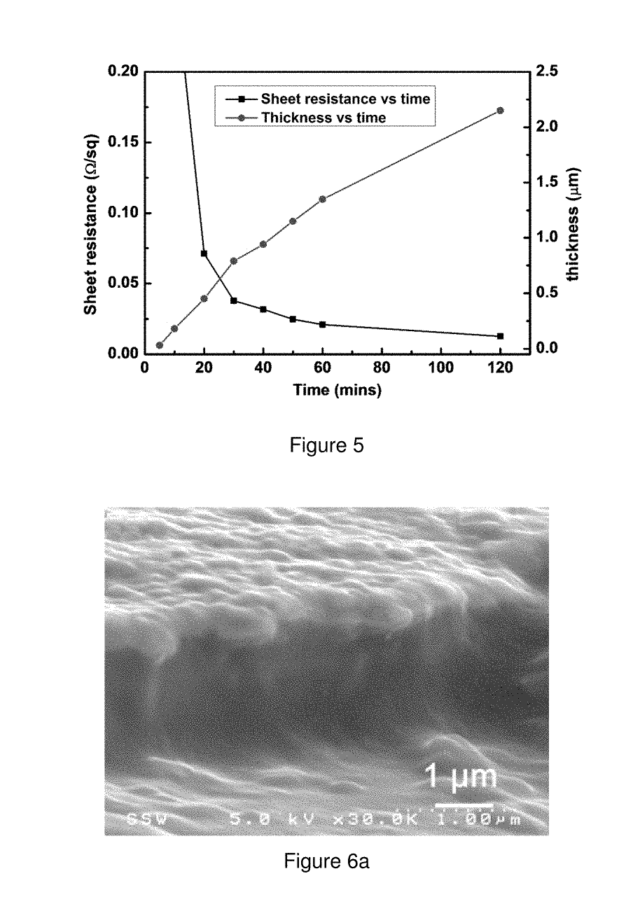

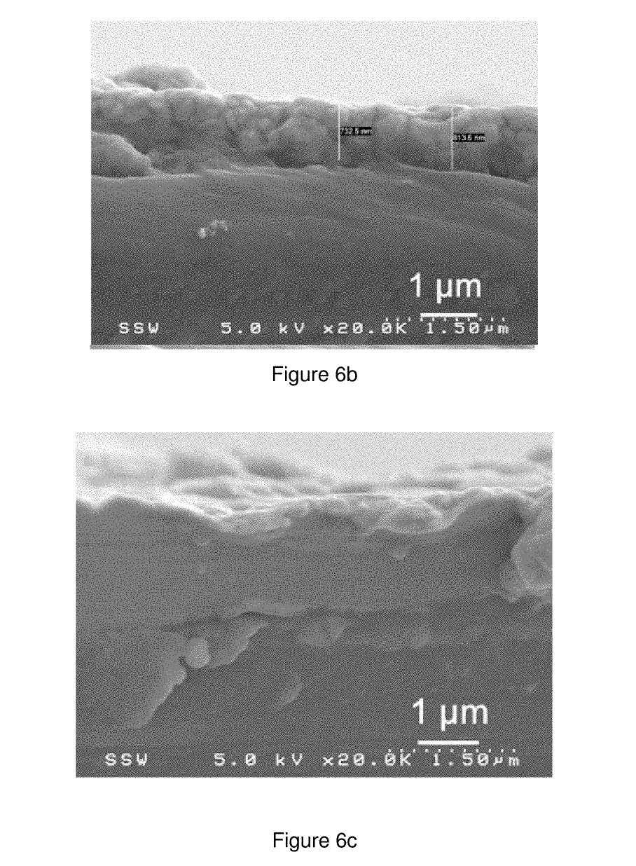

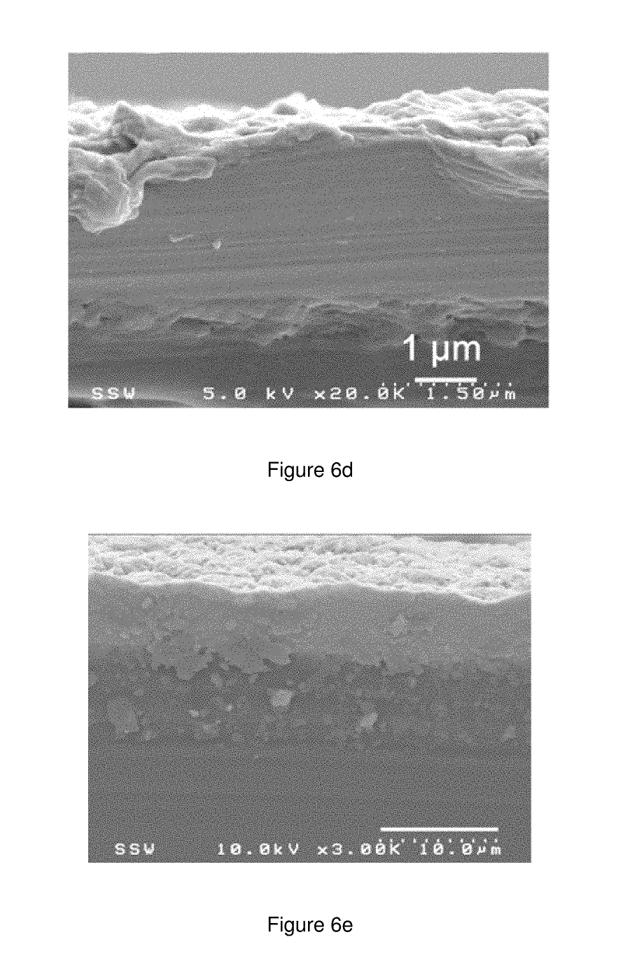

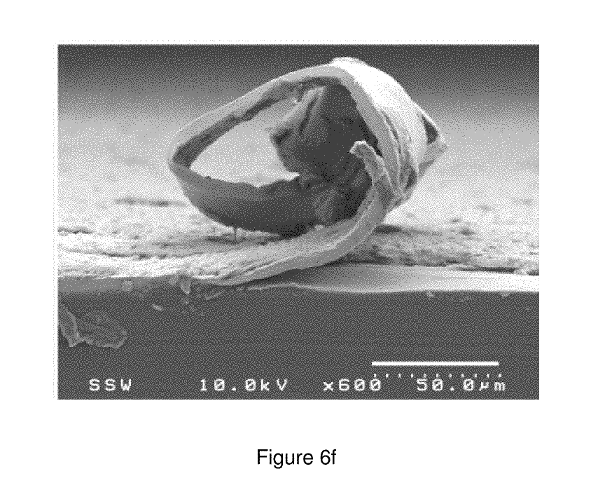

Further, the change of the thickness of copper layer with plating time is Investigated and the relevant images and curves were showed in FIG. 5 and FIGS. 6a to 6f inclusive. Meantime the corresponding conductivity at different thicknesses is also presented. It can be seen that within 2 hours, the copper layer grew in thickness continuously, and in the first hour, the copper layer had a faster growth rate which is attributed to high initial concentration of copper ions and pH value of copper plating bath. With the continuous consumption of copper ions and hydroxide ions during electroless plating process, the growth of copper became slower and slower until all the copper ions were consumed. The inventors have observed that after 12 hours of electroless plating, the thickness of copper layer that can be achieved is about 7 μm. Then the sheet resistance of copper layer was investigated.

The inventors have also found that the corresponding sheet resistance decreased dramatically with increasing the copper thickness. After 1 h of plating, the sheet resistance of copper layer can reach 0.021 Ω/sq. According to the equation ρ=Rs·t, in which p is the bulk resistivity, Rs is the sheet resistance, and t is the thickness of metal layer, we can calculate the bulk resistivity of as-deposited copper p. Based on the data of thickness and corresponding sheet resistance, the bulk resistivity of as-deposited copper layer at 10 mins was observed to be ca. 4.8×10⁻⁸ Ω·m, which is 2.7 times of normal bulk copper. With the thickness of copper increased, the bulk resistivity decreased dramatically and get closer and closer to bulk copper. When the plating time increased to 1 h, the bulk resistivity of copper layer turned into ca. 2.8×10⁻⁸ Ω·m, which is 1.6 times of normal bulk copper.

Furthermore, when the thickness of copper achieve to 7 μm, the conductivity of the copper layer can nearly reach 70% of normal bulk copper. Consequently, the thickened copper layer can not only increase the electrical conduction of the copper layer, but can also improve the electrical conductivity. High electrical conduction will obviously decrease the wastage of electrical energy and strongly favor the loading of high-power electronic components in flexible electronics.

In the following Examples 3-10, the components of each formulation are mixed together, formed into a coating solution, and applied to PET films, as in Example 1 and Example 2, to obtain film coatings possessing a smooth surface, an excellent long-last alkaline solution endurance, minimal tackiness and ultra-strong metal adhesion.

### Example 3

| COMPONENT | PERCENTAGE | | AMOUNT | |
|---|---|---|---|---|
| poly (4-vinyl pyridine) | 3 | w/v % | 3 | grams |
| (P4VP) | | | | |
| SU-8 | 0.2 | w/v % | 0.2 | grams |
| 1,4-dioxane | 50 | v/v % | 50 | mL |
| 2-propanol | 50 | v/v % | 50 | mL |

### Example 4

| COMPONENT | PERCENTAGE | | AMOUNT | |
|---|---|---|---|---|
| poly (4-vinyl pyridine) | 4 | w/v % | 4 | grams |
| (P4VP) | | | | |
| SU-8 | 0.2 | w/v % | 0.2 | grams |
| 1,4-dioxane | 50 | v/v % | 50 | mL |
| 2-propanol | 50 | v/v % | 50 | mL |

### Example 5

| COMPONENT | PERCENTAGE | | AMOUNT | |
|---|---|---|---|---|
| poly (4-vinyl pyridine) | 2 | w/v % | 2 | grams |
| (P4VP) | | | | |
| SU-8 | 0.1 | w/v % | 0.1 | grams |
| 1,4-dioxane | 50 | v/v % | 50 | mL |
| 2-propanol | 50 | v/v % | 50 | mL |

### Example 6

| COMPONENT | PERCENTAGE | | AMOUNT | |
|---|---|---|---|---|
| poly (4-vinyl pyridine) | 2 | w/v % | 2 | grams |
| (P4VP) | | | | |
| SU-8 | 0.15 | w/v % | 0.15 | grams |
| 1,4-dioxane | 50 | v/v % | 50 | mL |
| 2-propanol | 50 | v/v % | 50 | mL |

### Example 7

| COMPONENT | PERCENTAGE | | AMOUNT | |
|---|---|---|---|---|
| poly (4-vinyl pyridine) | 2.5 | w/v % | 2.5 | grams |
| (P4VP) | | | | |
| SU-8 | 0.2 | w/v % | 0.2 | grams |
| 1,4-dioxane | 50 | v/v % | 50 | mL |
| 2-propanol | 50 | v/v % | 50 | mL |

### Example 8

| COMPONENT | PERCENTAGE | | AMOUNT | |
|---|---|---|---|---|
| poly (4-vinyl pyridine) | 1 | w/v % | 1 | grams |
| (P4VP) | | | | |
| SU-8 | 0.2 | w/v % | 0.2 | grams |
| 1,4-dioxane | 50 | v/v % | 50 | mL |
| 2-propanol | 50 | v/v % | 50 | mL |

### Example 9

| COMPONENT | PERCENTAGE | | AMOUNT | |
|---|---|---|---|---|
| poly (4-vinyl pyridine) | 2 | w/v % | 2 | grams |
| (P4VP) | | | | |
| SU-8 | 0.05 | w/v % | 0.05 | grams |
| 1,4-dioxane | 50 | v/v % | 50 | mL |
| 2-propanol | 50 | v/v % | 50 | mL |

### Example 10

| COMPONENT | PERCENTAGE | | AMOUNT | |
|---|---|---|---|---|
| poly (4-vinyl pyridine) | 3 | w/v % | 3 | grams |
| (P4VP) | | | | |
| SU-8 | 0.3 | w/v % | 0.3 | grams |
| 1,4-dioxane | 50 | v/v % | 50 | mL |
| 2-propanol | 50 | v/v % | 50 | mL |

### Example 11

| COMPONENT | PERCENTAGE | | AMOUNT | |
|---|---|---|---|---|
| poly (4-vinyl pyridine) | 3.5 | w/v % | 3.5 | grams |
| (P4VP) | | | | |
| SU-8 | 0.3 | w/v % | 0.3 | grams |
| 1,4-dioxane | 50 | v/v % | 50 | mL |
| 2-propanol | 50 | v/v % | 50 | mL |

### Example 12

| COMPONENT | PERCENTAGE | | AMOUNT | |
|---|---|---|---|---|
| poly (4-vinyl pyridine) | 3 | w/v % | 3 | grams |
| (P4VP) | | | | |
| SU-8 | 0.4 | w/v % | 0.4 | grams |
| 1,4-dioxane | 50 | v/v % | 50 | mL |
| 2-propanol | 50 | v/v % | 50 | mL |

### Example 13

| COMPONENT | PERCENTAGE | | AMOUNT | |
|---|---|---|---|---|
| poly (4-vinyl pyridine) | 3 | w/v % | 3 | grams |
| (P4VP) | | | | |
| SU-8 | 0.6 | w/v % | 0.6 | grams |
| 1,4-dioxane | 50 | v/v % | 50 | mL |
| 2-propanol | 50 | v/v % | 50 | mL |

Regarding preparation of the coating solutions disclosed herein, it also may be prepared by adding the individual components of the inventive coating composition directly into solvent and then mixing to form the coating solution.

Preferably, the separate prepared solution is mixed together at a ratio of 1:1. We have found that the surface of modified PET film carries a lot of pyridine ligands attributed to the bonding of a lot of P4VP molecules, which can effectively capture various transitional metal ions from the solution. As we know, Pd²⁺ and Ag⁺ ions are two typical catalysts for electroless copper plating. They can be attacked by lone pair electrons of nitrogen atom of pyridine ligands to form strong coordination bonds. For example, once the modified PET film was soaked into AgNO₃ solution, the silver ions will be chemically absorbed onto the surface of PET. Different from simple physical absorption, chemical bonding is much stronger and the absorbed silver ions hardly escape from the surface. FIG. 1d shows the copper clad PET film after 1 h of electoless copper plating. As can be seen, copper can be fully coated on the whole PET substrate and shows good flexibility. The inventors have found that the distribution of the pits is homogeneous but the arrangement is irregular. With continuous copper plating, the copper layer become thicker and thicker, and the pits were filled gradually. FIGS. 4c and 4d show the surface morphologies of copper layers with 30 mins and 1 h of copper plating respectively. Obviously with increasing the copper plating time, the copper grain grows up, and the copper layer becomes denser. FIGS. 4e and 4f show the cross section of copper layer with 1 h and 12 h of copper deposition respectively.

The inventors have also observed that the thickness of copper layer is about 1.3-1.4 μm after 1 h of copper plating. Meanwhile the copper layer was attached onto the substrates tightly and no delamination was found when the present coating was applied. The Scotch tape test was used to check the adhesion of copper layer, and it was found that the copper layer cannot be delaminated off of the PET surface. Even with the thickness of 7 microns, copper layer still has a good adhesion to the substrate (FIG. 4f).

However, after certain types of treatments, such as exposure to an oxygen plasma or concentrated NaOH/H₂SO₄ exposure of the surfaces, or silane/other small molecules grafted surfaces, once the copper layer becomes thicker, the copper layer is prone to delaminate or bubble up from the substrate, which will seriously affect the quality of the copper deposition and hence the reliability of printed circuits. Also, it has been observed that, with the plating time increased, the underlayer of copper began to turn into a continuous phase, and the grainy structure disappeared gradually, which will be conducive for the improvement of the electrical conductivity.

Further, based on the process disclosed herein, it is possible to obtain ultra-thick copper layers on flexible PET substrates. Moreover, as is noted above, the surface modification did not affect the transparency and flexibility of PET film at all. Thus the modified film is very suitable to function as a flexible substrate for the printing of flexible circuits.

The method or process disclosed herein is very advantageous in that it provides a simple one step method for solution-based coating many kinds of substrates, from wood products, cellulose based paper or board products, plastics etc. The method is suitable for films of different sizes for large-scale surface modification, reduces film processing costs significantly while still meeting high-quality deposited metal requirements.

Another advantage of the present process is that it provides an effective coating to ensure that the surface of the flexible (or rigid) substrate can be conveniently produced with a thickness of more than 7 microns without flaking of the deposited metal circuit pattern, which is difficult to achieve with surface modification procedures, and the method allows the achievement of a thicker layer than may normally be obtained.

Another advantage of the present method is it provides a film coating which is compatible with printing techniques. The coating allows laser printing, inkjet printing, screen printing, gravure printing and similar techniques making reticle or functional catalyst deposited directly to the surface of the coating, thereby causing the pattern of the metal pattern to be formed during electroless deposition when the patterned substrate is immersed into an electroless plating bath containing a metal salt of a metal (e.g., Cu, Ni, Au, Ag etc.) from which the printed circuit is to be produced.

Based on the foregoing, it will be appreciated that the present disclosure provides, in one embodiment, a coating composition, comprising:

a mixture of two pre-prepared solutions, the first solution comprising poly (4-vinyl pyridine) dissolved in a first solvent which is any one of 2-propanol, methanol, ethanol, and acetone, the second solution comprising SU-8 dissolved in a second solvent which is any one of 1,4-dioxane, gamma-butyrolactone (GBL) and cyclopentanone, the poly (4-vinyl pyridine) being present in the mixture in a range from about 0.5% to about 4% by weight/volume of the composition, the SU-8 being present in the mixture in a range from about 0.05% to about 1% by weight/volume of the composition, the remainder of the composition up to 100% being the first and second organic solvents, the coating composition being used for use in coating a substrate.

In an embodiment, the first organic solvent is 2-propanol, and the second solvent is 1,4-dioxane.

In an embodiment, the 1,4-dioxane is present in the composition in a range of about 45% to about 50% by volume of the composition, and wherein the 2-propanol is present in the composition in a range of about 45% to about 50% by volume of the composition.

In an embodiment, the poly (4-vinyl pyridine) is characterized in that it has a molecular weight in a range from about of 60,000 to about 160,000 Daltons.

In an embodiment, the substrate is any one of a plastic, a semi-embossed film material, a cellulose based product, and a textile or fabric based product, a wood based product and a leather based product.

In an embodiment, the plastic is any one of polyester, polyimide, polyvinyl chlorides, polypropylenes, acrylics, acrylonitrile butadiene styrene (ABS) materials, polycarbonate materials, and polyethylene terephthalate (PET) materials.

In an embodiment, the textile or fabric based product is any one of nylon, cotton and polyester.

In an embodiment, the cellulose based product is any one of regular paper, synthetic paper, cellulose acetate film and cardboard.

In an embodiment, the semi-embossed film material is a semi-embossed plastic material.

In an embodiment, the composition further comprises surface tension adjustment agents for adjusting a surface tension of the composition.

In an embodiment, the surface tension adjustment agents include any one or combination of dynol, and carboxylates.

In an embodiment, the composition further comprises viscosity adjustment agents for adjusting a viscosity of the composition.

In an embodiment, the viscosity adjustment agents include any one of glycerol and poly(ethylene glycol)s.

In an embodiment, there is provided a method of coating substrates, comprising the steps of:

dissolving poly (4-vinyl pyridine) in a first solvent which is any one of 2-propanol, methanol, ethanol, and acetone to form a first solution;

dissolving SU-8 in a second solvent which is any one of 1,4-dioxane, gamma-butyrolactone (GBL) and cyclopentanone to form a second solution;

mixing the first and second solutions together form a uniform coating solution;

wherein the poly(4-vinyl pyridine) is present in a range from about 0.5% to about 4% by weight/volume of the composition, the SU-8 is present in a range from about 0.05% to about 1% by weight/volume of the composition, the remainder of the composition up to 100% being the first and second organic solvents;

applying an effective amount of said coating solution onto a surface of said substrate to form a film coating on said substrate surface;

drying the film coating on said substrate surface, and curing the coated film.

In an embodiment of the method, the step of curing the coated film is by heating at a temperature from about 80° C. to about 180° C. for a time period from about 15 minutes to about 40 minutes.

In an embodiment of the method, the step of curing the coated film is by exposure to UV or infrared radiation.

In an embodiment of the method, the first organic solvent is 2-propanol, and the second solvent is 1,4-dioxane.

In an embodiment of the method, the 1,4-dioxane is present in the composition in a range of about 45% to about 50% by volume of the composition, and wherein the 2-propanol is present in the composition in a range of about 45% to about 50% by volume of the composition.

In an embodiment of the method, the poly (4-vinyl pyridine) is characterized in that it has a molecular weight in a range from about of 60,000 to about 160,000 Daltons.

In an embodiment of the method, the substrate is any one of a plastic, a semi-embossed film material, a cellulose based product, and a textile or fabric based product, a wood based product and a leather based product.

In an embodiment of the method, the plastic is any one of polyester, polyimide, polyvinyl chlorides, polypropylenes, acrylics, acrylonitrile butadiene styrene (ABS) materials, polycarbonate materials, and polyethylene terephthalate (PET) materials.

In an embodiment of the method, the textile or fabric based product is any one of nylon, cotton and polyester.

In an embodiment of the method, the cellulose based product is any one of regular paper, synthetic paper, cellulose acetate film and cardboard.

In an embodiment of the method, the semi-embossed film material is a semi-embossed plastic material.

In an embodiment of the method, the composition further comprises surface tension adjustment agents for adjusting a surface tension of the composition.

In an embodiment of the method, the surface tension adjustment agents include any one or combination of dynol, and carboxylates.

In an embodiment of the method, the composition further comprises viscosity adjustment agents for adjusting a viscosity of the composition.

In an embodiment of the method, the viscosity adjustment agents include any one of glycerol and poly(ethylene glycol)s.

In an embodiment of the method, the step of the applying coating solution onto a substrate is any one of spin coating, dip coating, spray coating, air-blade coating, inkjet printing, gravure printing and screen printing.

In an embodiment of the method, the coating can be applied onto the substrate multiple times.

In an embodiment of the method, the method further provides a method of producing a printed circuit on a substrate coated in accordance with the present disclosure, comprising the steps of:

printing a pattern of a metal catalyst on a surface of the coated substrate with a liquid formulation containing the metal catalyst to form a pattern of the metal catalyst; and

immersing said coated substrate with the printed pattern located thereon in a electroless plating bath containing a dissolved metal salt and electrolessly depositing the metal of the dissolved metal salt for forming the printed circuit from the metal.

In an embodiment of this method the pattern of a circuit is printed using any one of inkjet printing, aerosol jet printing, and screen printing, spray coating, flexographic printing, spin coating.

In an embodiment of this method the formulation containing the metal catalyst includes any one of a salt of a noble metal such as silver nitride, palladium ion.

In summary, disclosed herein is a solution-based method for the fast surface modification of flexible plastics. The coating process can be completely executed under atmosphere at a relatively low temperature (80° C. to 180° C.), which renders this method suitable for large-scale surface modification of large-area flexible substrates. As-employed surface modifier was composed of polymer ligands and reactive adhesive, and they cannot only react with each other to form cross-linked polymer network, and also reactively bond with the substrates to produce a highly adhesive alkali resistant ligand layer on the surface of substrates for the selective and effective uptake of catalyst moieties.

With the coating compositions disclosed herein, and through electroless copper plating, high-quality copper layers with controllable thicknesses can be deposited on the flexible substrates. Ultra-thick copper layer (>7 μm) can be achieved by increasing the plating time, which well overcome the existing problem of thick copper deposition on flexible substrate and open a new way for real industrial production and application of flexible circuits.

Furthermore, double-side flexible circuits with higher integration can be fabricated fast on both sides of modified flexible plastics, which will save more cost and space for flexible electronic devices. In addition, this method for surface modification of flexible plastics can further be extended to other substances, such as 3D objects, paper, cloth, wood, and so on, which will provide a powerful tool for the metallization of isolated materials.

The foregoing description of the preferred embodiments of the invention has been presented to illustrate the principles of the invention and not to limit the invention to the particular embodiment illustrated. It is intended that the scope of the invention be defined by all of the embodiments encompassed within the following claims and their equivalents.

Therefore what is claimed is:

1. A coating composition, comprising:
a mixture of two pre-prepared solutions, the first solution comprising poly (4-vinyl pyridine) dissolved in a first solvent which is any one of 2-propanol, methanol, ethanol, and acetone, the second solution comprising SU-8 dissolved in a second solvent which is any one of 1,4-dioxane, gamma-butyrolactone (GBL) and cyclopentanone, the poly (4-vinyl pyridine) being present in the mixture in a range from about 0.5% to about 4% by weight/volume of the composition, the SU-8 being present in the mixture in a range from about 0.05% to about 1% by weight/volume of the composition, the remainder of the composition up to 100% being the first and second organic solvents, the coating composition being used for use in coating a substrate.

2. The coating composition according to claim 1, wherein the first organic solvent is 2-propanol, and the second solvent is 1,4-dioxane.

3. The coating composition according to claim 2, wherein the 1,4-dioxane is present in the composition in a range of about 45% to about 50% by volume of the composition, and wherein the 2-propanol is present in the composition in a range of about 45% to about 50% by volume of the composition.

4. The coating composition of claim 1, wherein said poly (4-vinyl pyridine) is characterized in that it has a molecular weight in a range from about of 60,000 to about 160,000 Daltons.

5. The coating composition according to claim 1, wherein the substrate is any one of a plastic, a semi-embossed film material, a cellulose based product, and a textile or fabric based product, a wood based product and a leather based product.

6. The coating composition according to claim 5, wherein the plastic is any one of polyester, polyimide, polyvinyl chlorides, polypropylenes, acrylics, acrylonitrile butadiene styrene (ABS) materials, polycarbonate materials, and polyethylene terephthalate (PET) materials.

7. The coating composition according to claim 5, wherein the textile or fabric based product is any one of nylon, cotton and polyester.

8. The coating composition according to claim 5, wherein the cellulose based product is any one of regular paper, synthetic paper, cellulose acetate film and cardboard.

9. The coating composition according to claim 5, wherein the semi-embossed film material is a semi-embossed plastic material.

10. The coating composition according to claim 1 wherein the composition further comprises surface tension adjustment agents for adjusting a surface tension of the composition.

11. The coating composition according to claim 10 wherein the surface tension adjustment agents include any one or combination of dynol, and carboxylates.

12. The coating composition according to claim 1 wherein the composition further comprises viscosity adjustment agents for adjusting a viscosity of the composition.

13. The coating composition according to claim 12 wherein the viscosity adjustment agents include any one of glycerol and poly(ethylene glycol)s.

14. A method of coating substrates, comprising the steps of:
dissolving poly (4-vinyl pyridine) in a first solvent which is any one of 2-propanol, methanol, ethanol, and acetone to form a first solution;
dissolving SU-8 in a second solvent which is any one of 1,4-dioxane, gamma-butyrolactone (GBL) and cyclopentanone to form a second solution;
mixing the first and second solutions together form a uniform coating solution;
wherein the poly(4-vinyl pyridine) is present in a range from about 0.5% to about 4% by weight/volume of the composition, the SU-8 is present in a range from about 0.05% to about 1% by weight/volume of the composition, the remainder of the composition up to 100% being the first and second organic solvents;
applying an effective amount of said coating solution onto a surface of said substrate to form a film coating on said substrate surface;
drying the film coating on said substrate surface, and
curing the coated film.

15. The method according to claim 14, wherein the step of curing the coated film is by heating at a temperature from about 80° C. to about 180° C. for a time period from about 15 minutes to about 40 minutes.

16. The method according to claim 14, wherein the step of curing the coated film is by exposure to UV or infrared radiation.

17. The method according to claim 14, wherein the first organic solvent is 2-propanol, and the second solvent is 1,4-dioxane.

18. The method composition according to claim 17, wherein the 1,4-dioxane is present in the composition in a range of about 45% to about 50% by volume of the composition, and wherein the 2-propanol is present in the composition in a range of about 45% to about 50% by volume of the composition.

19. The method according to claim 14, wherein said poly (4-vinyl pyridine) is characterized in that it has a molecular weight in a range from about of 60,000 to about 160,000 Daltons.

20. The method according to claim 14, wherein the substrate is any one of a plastic, a semi-embossed film material, a cellulose based product, and a textile or fabric based product, a wood based product and a leather based product.

21. The method according to claim 20, wherein the plastic is any one of polyester, polyimide, polyvinyl chlorides, polypropylenes, acrylics, acrylonitrile butadiene styrene (ABS) materials, polycarbonate materials, and polyethylene terephthalate (PET) materials.

22. The method according to claim 20, wherein the textile or fabric based product is any one of nylon, cotton and polyester.

23. The method according to claim 20, wherein the cellulose based product is any one of regular paper, synthetic paper, cellulose acetate film and cardboard.

24. The method according to claim 20, wherein the semi-embossed film material is a semi-embossed plastic material.

25. The method according to claim 14, wherein the composition further comprises surface tension adjustment agents for adjusting a surface tension of the composition.

26. The method according to claim 25, wherein the surface tension adjustment agents include any one or combination of dynol, and carboxylates.

27. The method according to claim 14, wherein the composition further comprises viscosity adjustment agents for adjusting a viscosity of the composition.

28. The method according to claim 27 wherein the viscosity adjustment agents include any one of glycerol and poly(ethylene glycol)s.

29. The method according to claim 14, wherein the step of the applying coating solution onto a substrate is any one of spin coating, dip coating, spray coating, air-blade coating, inkjet printing, gravure printing and screen printing.

30. The method according to claim 14, wherein the coating can be applied onto the substrate multiple times.

31. A method of producing a printed circuit on a substrate, comprising the steps of:
dissolving poly (4-vinyl pyridine) in a first solvent which is any one of 2-propanol, methanol, ethanol, and acetone to form a first solution;
dissolving SU-8 in a second solvent which is any one of 1,4-dioxane, gamma-butyrolactone (GBL) and cyclopentanone to form a second solution;
mixing the first and second solutions together form a uniform coating solution;
wherein the poly(4-vinyl pyridine) is present in a range from about 0.5% to about 4% by weight/volume of the composition, the SU-8 is present in a range from about 0.05% to about 1% by weight/volume of the composition, the remainder of the composition up to 100% being the first and second organic solvents;
applying an effective amount of said coating solution onto a surface of said substrate to form a film coating on said substrate surface;
drying the film coating on said substrate surface;
curing the coated film;
printing a pattern of a metal catalyst on a surface of the coated substrate with a liquid formulation containing the metal catalyst to form a pattern of the metal catalyst; and
immersing said coated substrate with the printed pattern located thereon in a electroless plating bath containing a dissolved metal salt and electrolessly depositing the metal of the dissolved metal salt for forming the printed circuit from the metal.

32. The method according to claim 31, wherein said pattern of a circuit is printed using any one of inkjet printing, aerosol jet printing, and screen printing, spray coating, flexographic printing, spin coating.

33. The method according to claim 31 wherein the formulation containing the metal catalyst includes any one of a salt of a noble metal such as silver nitride, palladium ion.
